(19) United States
(12) Patent Application Publication
(10) Pub. No.: US 2005/0271816 A1
(43) Pub. Date: Dec. 8, 2005

(54) Material comprising a surface consisting of a metal carbide-carbon composite and a method for producing the same

(76) Inventor: Frank Meschke, Buchenberg (DE)

Correspondence Address: NATH & ASSOCIATES, 1030 15th STREET, NW, 6TH FLOOR, WASHINGTON, DC, 20005, US

(21) Appl. No.: 10/522,533

(22) PCT Filed: Jul. 24, 2003
(86) PCT No.: PCT/EP03/08177

§ 371 Date: Jan. 27, 2005

(30) Foreign Application Priority Data
Aug. 1, 2002 (DE) 102 35 269.0

(51) Int. Cl. C23C 16/00

(52) U.S. Cl. 427/255.4

(57) ABSTRACT

The invention relates to a material comprising a surface consisting of a metal carbide-carbon composite. Said material is characterized in that geometrically defined areas of the metal carbide surface contain carbon bonded by a material union to a depth of between 0.01 and 1,000 μm.

The invention relates to material having a surface made from a metal carbide/carbon composite, and to a process for producing it.

On account of their high hardness and the resultant resistance to wear, their high thermal conductivity, the extremely good resistance to corrosion and the excellent strength, SiC materials as representatives of metal carbides are eminently suitable for use as bearings and seals in chemical plant equipment (for example pumps). Components made from titanium carbide (TiC), tungsten carbide (WC) and boron carbide (B₄C) are also particularly wear-resistant. In friction systems, these hard materials are often used against other or the same hard materials (hard/hard pairing) However, in sliding and friction systems with little or no lubrication (such a pump bearings and seals), a high coefficient of friction causes a huge temperature rise to over 200° C. within a few minutes, which is associated with considerable wear to the sliding surfaces followed by complete destruction of the contact surfaces. Therefore, long-term resistance to dry running conditions is not achieved.

To attenuate the evolution of temperature in dry-running conditions and with little lubrication in hard/hard-paired friction systems, the current state of the art involves incorporating a solid lubricant, generally particulate carbon in the form of graphite, in the SiC. Materials of this type can be produced either by powder metallurgy or by reaction bonding. SiC/graphite materials which have been produced by powder metallurgy using a graphite-containing SiC starting powder are described in U.S. Pat. No. 4,525,461, EP-A 850898 and in DE-A 10111225. U.S. Pat. No. 4,525,461 describes graphite-containing SiC materials, with a base material composed of fine-grained sintered SiC. Patents EP-A 850898 and DE-A 10111225 describe sintered SiC materials with a coarse-grained, bimodal microstructure. Wacker Chemie GmbH, Kempten, Germany, offer a material of this type under the name EKasic® G Siliciumkarbid.

Si—SiC materials which are reaction-bonded through silicon infiltration are described in the literature (for example Handbook of Ceramic Hard Materials, Vol 2, Edt. Ralf Riedel Wiley-VCH(2000) pp. 683-748). The silicon content is typically 10-15% by volume, seldom less than 5% by volume. These Si—SiC materials may additionally include up to 40% by volume of graphite. In all the graphite-containing SiC materials mentioned, the graphite is distributed randomly and homogeneously in the solid SiC base material.

The ability of these SiC materials to withstand dry running conditions can be improved by increasing the graphite content. However, for process engineering reasons there is an upper limit imposed on the graphite content. For example in sintered SiC (S—SiC), more than 15% by volume can only be realized at the cost of considerable reductions in the sintered density, which imposes restrictions on the ability of sliding ring seals to function. On account of this limitation, the SiC materials cannot be considered to have a long-term ability to run under dry conditions in what are known as hard/hard pairings, in which the material is under frictional load against itself or against other hard materials.

An alternative solution for incorporating a solid lubricant into a sliding-contact bearing material is described by PCT application WO 02/02956 A1 in the name of SPS Bleistahl. After machining (turning, milling and drilling, e.g. in the unsintered state), ceramic sliding-contact bearings have a solid lubricant (graphite, boron nitride) pressed into them. Subsequent sintering allows the solid lubricant elements, which are generally of a size of several millimeters and cylindrical, to shrink in. The solid lubricant elements are bonded nonpositively but not cohesively. This process does not allow materials to be incorporated in any desired form or surface coverage, since empty spaces are drilled into the SiC components and these spaces have cores made from graphite or the like fitted into them. It is therefore in principle only suitable for round cores. The cylindrical cores are preferably oriented perpendicular to the sliding surface. The surface coverage of the graphite in the sliding surface of the material disclosed here is limited. If the level of materials incorporated is too high, it is necessary to accept considerable restrictions in the strength and rigidity of the component. Moreover, heating of the material potentially leads to loosening of the cores.

It is also part of the prior art for the sliding friction partners to be covered with a friction-reducing carbon layer. Diamond-like carbon (DLC) layers, diamond layers or graphite layers can be applied to the surface by chemical vapor deposition (CVD). The abstract of JP04041590 discloses the production of an SiC shaped body with a graphite layer using the CVD process.

Another process for producing SiC with a continuous graphite covering layer is described in patent application DE 10045339 A1 (EP 1188942 A1). In this “high-temperature process”, the thermal decomposition of SiC into carbon and evaporating Si phases at temperatures around 2000° C. in vacuo is utilized. The surface of the SiC is not covered with a continuous layer of carbon, but rather is converted into such a layer. The layer which is formed is in (partially) crystalline form with a high graphite content.

Another process for producing SiC with continuous graphite covering layers is based on what is known as the chlorine gas process. This process exploits the fact that silicon carbide can be decomposed into silicon phases (silicon tetrachloride) and carbon at temperatures of over 800° C. with the aid of a halogen-containing gas, such as for example chlorine. This reaction has been known since 1914 and is mentioned in standard material science textbooks. (Encyclopedia of Advanced Materials, Pergamon Press, page 2455-2461, 1994). It is described in the literature that depending on the concentration of the halogen-containing gas, the temperature and time of the process, the resulting carbon remains on the surface of metal carbides, in particular SiC, in the form of diamond, diamond-like carbon, graphite or amorphous carbon (Y. G. Gogotsi, I. Jeon and M. J. McNallan, Carbon coating on silicon carbide by reaction with chlorine-containing gases, J. Mater. Chem. 1997, 7(9), p. 1841-1848 and WO 01/16054 from 9.1.1999). Ageing in a gas enriched with 2%-3.5% by weight of chlorine at temperatures from 800°-1200° C. and pressures from 0-100 atmosphere are mentioned as suitable boundary conditions. Similarly to in DE 10045339 A1 (EP 1188942 A1), the carbon remains as a continuous covering layer on the SiC.

On account of their bonding strength, their limited layer thicknesses and the limited thermal stability, continuous diamond and DLC covering layers have only a limited service life, generally from a few minutes to several hours, under dry-running conditions. Although the continuous graphite covering layers have advantages with regard to thermal stability and frictional losses, their low hardness means that they become worn very quickly.

It is an object of the present invention to provide a material which is better able to withstand frictional load than a known SiC-based or B₄C-based material or than a material with a continuous friction-reducing covering layer.

The object is achieved by a material having a surface formed from a metal carbide/carbon composite, characterized in that the metal carbide surface contains carbon which is cohesively bonded in geometrically defined regions down to a depth of from 0.01 to 1000 μm.

One or more amorphous and/or crystalline phases can be incorporated in the metal carbide. The amorphous and/or crystalline phase is, for example, graphite, silicon or yttrium-aluminum garnet, cobalt. Materials of this type, but without the layer of carbon according to the invention at the surface in defined regions down to a depth of from 0.01 to 1000 μm, form part of the prior art (reaction-bonded SiSiC, liquid-sintered SiC, tungsten carbide or boron carbide). It is preferable for the surface of the material which is provided with a layer of carbon to be planar.

The metal carbide is preferably SiC. It is preferably an SiC sintered body or a body formed from reaction-bonded Si—SiC or an SiC covering layer on any desired substrate.

An SiC sintered body with a porosity of 0-15% by volume is particularly preferred.

The SiC sintered body preferably consists of sintered SiC (including recrystallized SiC) comprising 0-30% by weight of one or more foreign phases. Examples of permitted foreign phases include graphite, silicon and yttrium-aluminum garnet. The foreign phase content should be as low as possible. SiC sintered bodies with a foreign phase content of <5% by weight are particularly preferred.

The SiC sintered body very particularly preferably consists of sintered SiC.

The sintered SiC contains up to 5% by weight of boron and/or aluminum and also includes 0-25% by weight of free, particulate carbon. The sintered SiC preferable has a coarse-grained, bimodal microstructure with a grain size of between 1 μm and 1500 μm.

The carbon layer which according to the invention is present down to a depth of from 0.01 to 1000 μm in defined subregions of the surface is cohesively bonded to the SiC and therefore adheres particularly well. The carbon is preferably amorphous carbon, partially crystalline carbon, graphite, diamond-like carbon, diamond or mixtures thereof. It is preferably a graphite-containing carbon, particularly preferably graphite. The carbon is a product of an etching process using chlorine gas or a high-temperature decomposition process. Therefore, the carbon may be in completely amorphous or fully crystallized form. However, it may also comprise a mixture of amorphous and crystalline phases. This is what is to be understood by “partially crystalline” in the context of the present invention.

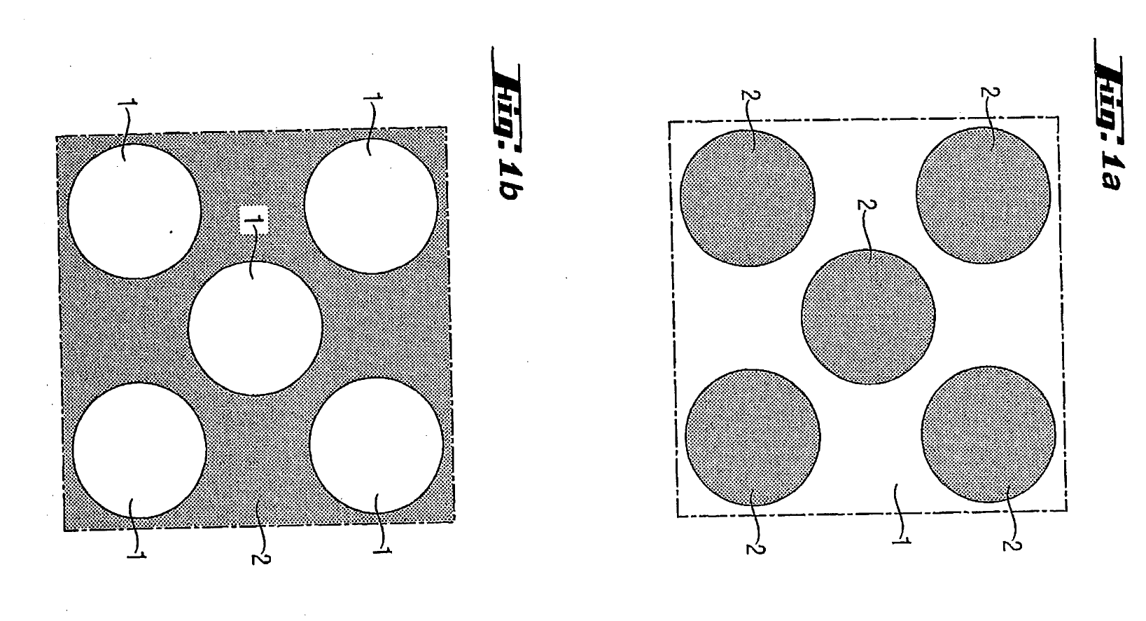

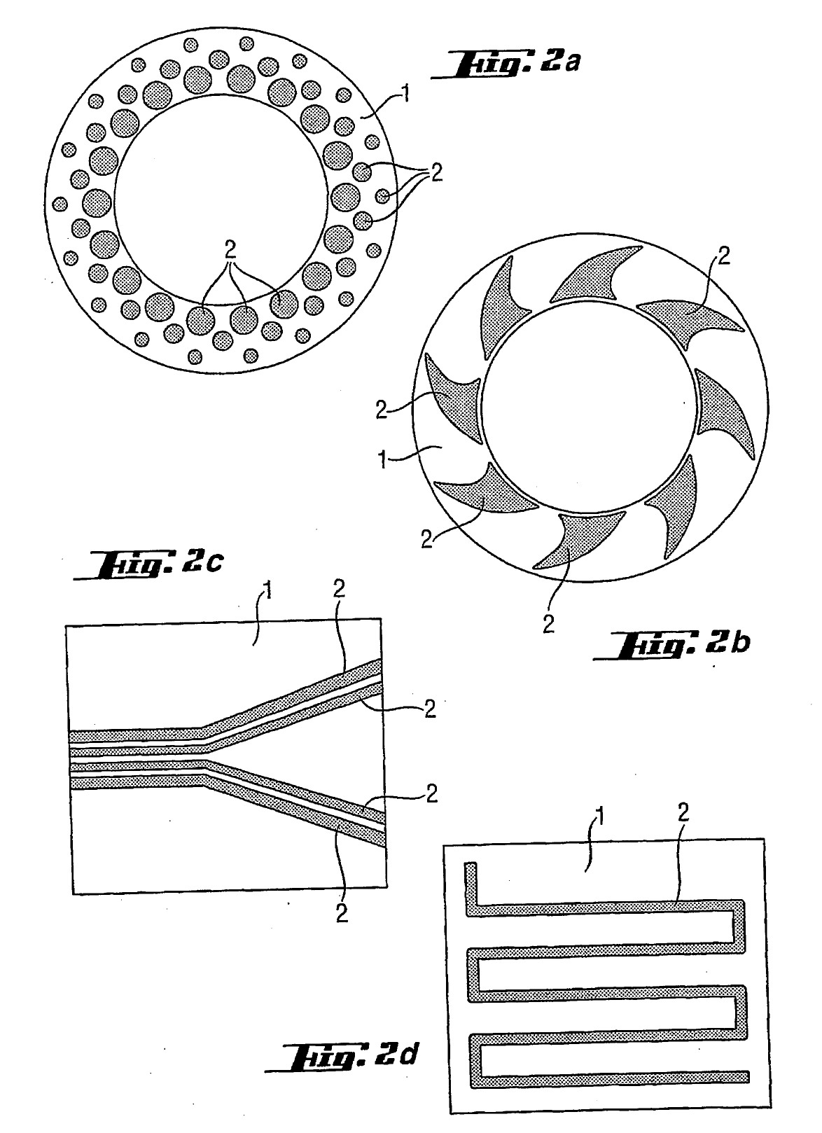

The carbon subregions of the surface which are present according to the invention are of any random but desired, predefined form. Examples of the form of the subregions are circular areas or non-round shapes, such as strips, sickles or the like. FIGS. 1 and 2 show a few examples of carbon subregions on a metal carbide surface. In surface regions which are subject to high frictional loads, the incorporations of carbon of predefined form make up from 0.1-99%, preferably 5-95%, particularly preferably 15-90%, especially preferably 25-80%, of the surface area.

It is preferable for the thickness of the carbon elements to be 0.01-50 μm.

The geometric shape of the graphite incorporations is ideally selected in such a way as to provide particularly efficient lubrication in the sliding surface.

The SiC which remains between the incorporations of carbon at the surface represents carrier components which are difficult to remove by abrasion on frictional contact with a hard material, thereby considerably improving the abrasion properties of the material according to the invention compared to those of a continuous graphite covering layer.

Examples of applications for the materials according to the invention are hard/hard-paired sliding-contact bearings and sliding ring seals which are provided with a locally concentrated graphite layer at those locations of the surface at which the frictional load is highest, such that solid-state lubrication is ensured and damage resulting from a temperature rise is prevented even under very extreme conditions of lack of liquid lubrication or under dry-running conditions.

The statements which have been made here on the basis of the example of an SiC sintered body/an SiC surface also apply analogously to other metal carbide sintered bodies/metal carbide surfaces, for example formed by B₄C or TiC or WC.

Furthermore, the invention relates to a process for producing a shaped body, characterized in that a workpiece with a metal carbide surface is heated in a defined region of its surface, in the presence of a reaction gas, a shielding gas or in a vacuum, by means of a radiation source, in such a manner that in this region the metal carbide is locally converted into carbon.

The metal carbide is preferably SiC. The statements which are made below in connection with SiC also apply analogously to other metal carbides.

The process according to the invention allows a high degree of flexibility with regard to the configuration of graphite surfaces and their distribution in an SiC surface. For example, the process according to the invention allows SiC-based sliding-contact bearings and sliding ring seals to be provided with a local concentration of graphite at the locations at which the frictional load is highest, such that sufficient solid-state lubrication is always ensured—even under very extreme lack of liquid lubrication or under dry-running conditions—and damage resulting from an excessive temperature rise is prevented.

Any desired metal carbide, preferably any desired SiC material, is suitable as starting material for the process according to the invention. Materials which bear a metal carbide covering layer on any desired substrate are also suitable.

In one process variant, the metal carbide is locally irradiated with the aid of a radiation source and in the predetermined regions is thus heated to 600-1500° C., and at the same time the metal carbide surface is exposed to a reaction gas, the reaction gas being such that in the predetermined temperature range it is able to dissolve the metal of the metal carbide and leave behind carbon.

The metal carbide material which has been irradiated with the radiation source may itself already have been preheated. The carbon which is produced by the irradiation is in the form of amorphous or partially crystalline carbon, graphite, diamond or another modification or a mixture of these variants.

The reaction gas used is preferably a carrier gas mixed with a halogen or halogen mixture (fluorine, chlorine, bromine, iodine or mixtures thereof). The preferred halogen is chlorine. The inert carrier gas used is preferably argon, helium, krypton or nitrogen, particularly preferably argon. HCl can also be used as an alternative.

To stimulate the formation of certain carbon modifications, it is additionally possible for from 0.1 to 99% by weight, preferably 0.1 to 10% by weight, of hydrogen to be added to the reaction gas as an additive.

Alternatively, the surface which is irradiated with a beam source may also be exposed to a vacuum or shielding gas, preferably with a gas pressure of lower than 100 mbar, particularly preferably lower than 10⁻³ mbar, the local temperature then being locally heated to more than 1500° C. and less than 2200° C. with the aid of the radiation source. In this case, metal carbide decomposes without the involvement of foreign elements into metal and carbon. The shielding gas is preferably argon or nitrogen.

The radiation source used may, for example, be a laser, a microwave or an electron beam. A laser is preferably used if the reaction gas is used. Scanning optics are ideally connected to the laser. The scanner optics are used for particularly rapid guidance of the laser beam. Preferred lasers are neodymium-YAG lasers or CO₂ lasers. It is particularly preferably to use a neodymium-YAG laser. When using a vacuum, an electron beam is particularly suitable for the local heating and conversion.

The process parameters for the laser, in particular lamp current, pulse length, interpulse period, focal length and irradiation time, can be varied over a wide range. One possible set of parameters comprises, for example, a lamp current of 540 mA, a pulse length of 0.32 ms, an interpulse period of 18.4 ms, a focal position of 150 mm and an irradiation time of 20 s.

The local irradiation with a laser, in particular using scanner optics, makes it possible to convert any desired regions of a metal carbide surface into carbon. In this case, there are no limits on the geometry and the proportion of the surface area.

In addition to thin-walled metal carbide components, it is also possible for metal carbide covering layers on a substrate to be converted locally in any desired form and in any desired proportions by volume completely into carbon by means of the process according to the invention.

The process according to the invention allows the production of metal carbide/carbon composite material surfaces which are able to withstand high frictional loads and, moreover, are capable of running under dry conditions for a prolonged period of time, for example for sliding-contact bearings and hard/hard-paired sliding ring seals. Components made from this material also satisfy the demand for high component rigidity, strength and thermal stability. Suitable applications include all kinds of friction systems which are subject to frictional loads, in particular dry-running sliding-contact bearings, dry-running sliding ring seals, dry-running piston pumps, compressors and valve bearings.

FIGS. 1a and 1b diagrammatically depict two complementary examples of a metal carbide/carbon composite according to the invention with 50% of the surface area covered by the carbon layer. The metal carbide surface is denoted by 1, and the carbon incorporations are denoted by 2.

FIGS. 2a, 2b, 2c and 2d diagrammatically depict examples of metal carbide/carbon composite surfaces with structured carbon (graphite) incorporations.

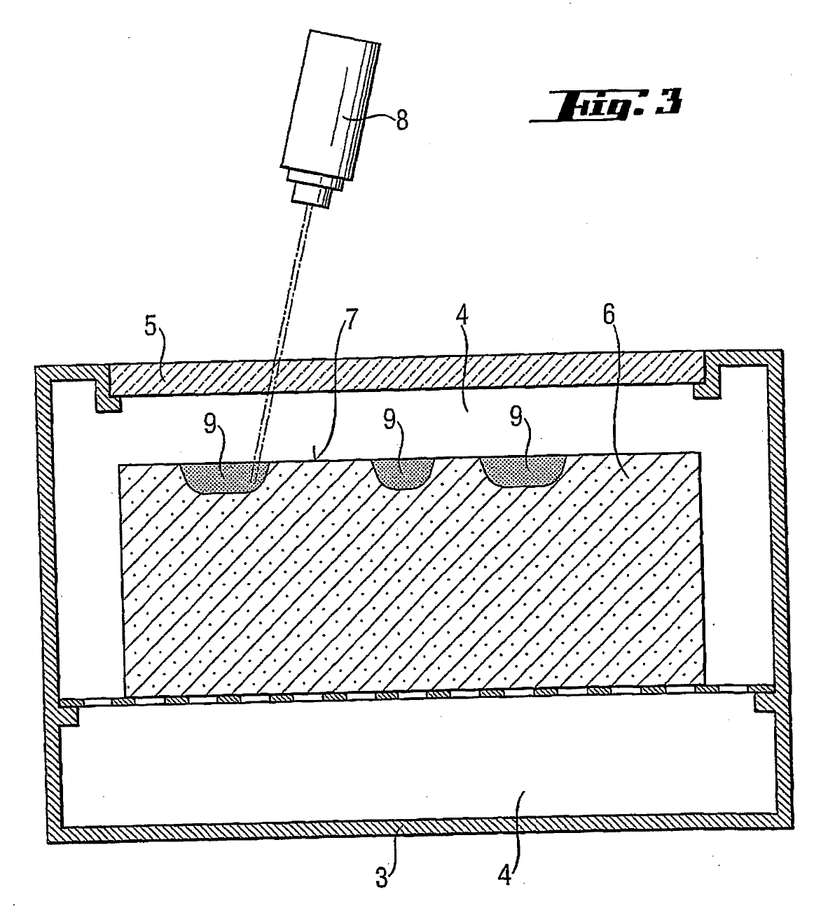

FIG. 3 diagrammatically depicts the production process according to the invention for locally converting metal carbide into carbon. An optionally preheated workpiece (6) with a metal carbide surface (7) is aged in a chamber (3) containing a reaction gas (4) and having a glass window (5). The surface (7) is locally heated using a laser (8) so as to stimulate a conversion into carbon (9).

The carbon constituents are electrically conductive and can therefore also perform secondary roles as well as improving the lubrication conditions if they structured accordingly. Such functions include, for example, the dissipation of electrical potential or use as a heating element.

The following examples serve to further explain the invention.

### EXAMPLE 1

An axial bearing made from fine-grained sintered S—SiC (EKasic® F Siliciumkarbid), commercially available from Wacker Chemie GmbH, Munich, Germany, is exposed to a gas composed of Ar/2% chlorine in a reaction chamber. The end side of the bush (external diameter 32 mm, internal diameter 18 mm) is locally heated to 800° C. using an Nd—YAG laser (1.06 μm wavelength). The beam is guided in such a way that circular areas of graphite-containing carbon with a diameter of 500 μm are formed distributed uniformly in the surface of the axial load-bearing surface. The graphite forms 75% of the surface area. The thickness of the carbon incorporations is 5 μm.

### EXAMPLE 2

A sliding-contact bearing shaft protection sleeve made from coarse-grained sintered S—SiC (EKasic® C Siliciumkarbid), commercially available from Wacker Chemie GmbH, Kempten, Germany, is mounted on a rotating shaft in a reaction chamber and then a gas composed of Ar/2% chlorine flows over it. An Nd—YAG laser (1.06 μm wavelength) locally heats the component to 1000° C., where it induces conversion into graphite-rich carbon. The laser and sliding-contact bearing are guided in such a way that a helical track of graphite-containing carbon with a width of 2 mm is formed in the cylindrical outer surface of the SiC shaft protection sleeve. The thickness of the carbon incorporations is 5 μM.

### EXAMPLE 3

A sliding ring made from fine-grained sintered S—SiC (EKasic® F Siliciumkarbid, Wacker Chemie GmbH, Munich, internal diameter 44 mm, wall thickness 4 mm) is preheated to 400° C. in the reaction chamber using a second laser source. A reaction gas consisting of argon together with 2% of chlorine/2% of H₂ flows over the specimen. The Nd—YAG (1.06 μm) primary laser locally heats the sliding surface to 900° C. This primary laser is guided in such a way that triangular surfaces are formed at the inner edge. The orientation and spacing of the triangles is selected in such a way that at the inner edge graphite-containing carbon covers 80% of the surface area. The incorporations extend down to a depth of 10 μm.

### EXAMPLE 4

A sliding ring with dimensions as in Example 3 made from coarse-grained sintered S—SiC with particulate graphite incorporations (available as EKasic® G Siliciumkarbid from Wacker Chemie GmbH, Munich, Germany) was treated as described in Example 3. On account of the additional graphite particles in the base material, the carbon content in the SiC surface close to the inner edge of the sliding ring rises to over 80%. The graphite particles of the base material are embedded in the graphite incorporations formed.

### EXAMPLE 5

A fine-grained gas sealing ring made from liquid-phase-sintered SiC with yttrium-aluminum garnet as crystalline secondary phase (EKasic® T Siliciumkarbid), internal diameter 200 mm, wall thickness 30 mm, is exposed to a flowing gas mixture of argon together with 2% of chlorine/2% of H₂ in the reaction chamber. An Nd—YAG primary laser locally heats the sliding surface to 1000° C. The primary laser is guided in such a way that lines with a width of 50 μm run radially inward from the outer edge.

### EXAMPLE 6

A sliding ring made from fine-grained sintered S—SiC (EKasic® F Siliciumkarbid, Wacker Chemie GmbH, Munich) in accordance with Example 3 is preheated to 700° C. in the reaction chamber using a second laser source. A reaction gas consisting of argon together with 3% of chlorine flows over the specimen. A diode laser (808 nm) primary laser locally heats the sliding surface to 1300° C. This primary laser is guided in such a way that sickles of graphite-containing carbon are formed, covering more than 60% of the surface area. The orientation of the sickles with respect to the direction of rotation is selected in such a way that the solid lubricant is effectively carried in the regions where there is a lack of lubrication. The incorporations extend down to a depth of 10 μm.

### EXAMPLE 7

An axial bearing plate made from coarse-grained sintered S—SiC (EKasic® C Siliciumkarbid), Wacker Chemie GmbH, Munich, external diameter 65 mm, internal diameter 45 mm) is preheated to 1500° C. in a reaction chamber with a vacuum of lower than 1×10⁻⁴ mbar using a defocused 30 kV electron beam. At the same time, disk-like carbon incorporations as solid lubricant cushions are introduced as a regular pattern of dots at a local temperature of 1950° C. by means of a focused electron beam. The orientation and spacing of the lubricating cushions are selected in such a way that the surface coverage amounts to 70%. The incorporations extend down to a depth of 200 μm.

1. A process for producing a shaped body, characterized in that a material with a metal carbide surface is heated in a defined region of its surface, in the presence of a reaction gas, a shielding gas or in a vacuum, by means of a radiation source, in such a manner that in this region the metal carbide is locally converted into carbon.

2. The process as claimed in claim 1, characterized in that the metal carbide is locally irradiated with the aid of a radiation source and in the process is heated to 600-1500° C., and at the same time the metal carbide surface is exposed to a reaction gas, the reaction gas being such that in the predetermined temperature range it is able to dissolve the metal of the metal carbide and leave behind carbon.

3. The material as claimed in claim 2, characterized in that the reaction gas used is a carrier gas mixed with halogen.

4. The process ac claimed in claim 3, characterized in that the halogen used is chlorine and the carrier gas used is argon.

5. The process as claimed in claim 1, characterized in that the surface which is irradiated with a radiation source is locally heated to more than 1500° C. and less than 2200° C. and is exposed to a vacuum or shielding gas, with metal carbide decomposing into metal and carbon without the involvement of foreign elements.

6. The process as claimed claim 1, characterized in that the radiation source used is a laser, a microwave or an electron beam.
